(19) United States
(12) Patent Application Publication
(10) Pub. No.: US 2021/0162560 A1
(43) Pub. Date: Jun. 3, 2021

(54) POLISHING PAD, PREPARATION METHOD THEREOF, AND PREPARATION METHOD OF SEMICONDUCTOR DEVICE USING SAME

(71) Applicant: SKC CO., LTD., Gyeonggi-do (KR)

(72) Inventors: Jaein AHN, Gyeonggi-do (KR); Kyung Hwan KIM, Gyeonggi-do (KR); Sunghoon YUN, Gyeonggi-do (KR); Hyeyoung HEO, Gyeonggi-do (KR); Jang Won SEO, Gyeonggi-do (KR)

(21) Appl. No.: 17/104,829

(22) Filed: Nov. 25, 2020

(30) Foreign Application Priority Data
Nov. 28, 2019 (KR) 10-2019-0155407

(51) Int. Cl. B24B 37/24; H01L 21/306

(52) U.S. Cl. CPC B24B 37/245; H01L 21/30625

(57) ABSTRACT

Embodiments relate to a polishing pad for use in a chemical mechanical planarization (CMP) process of semiconductors, a process for preparing the same, and a process for preparing a semiconductor device using the same. According to the embodiments, it is possible to provide a polishing pad in which the average diameter of the plurality of pores contained in the polishing pad, the sphericity of the plurality of pores, and the volume ratio thereof are adjusted, thereby enhancing the polishing speed and reducing surface such defects as scratches and chatter marks appearing on the surface of a semiconductor substrate.

The present application claims priority of Korean patent application numbers 10-2019-0155407 filed on Nov. 28, 2019. The disclosure of each of the foregoing applications is incorporated herein by reference in its entirety.

### TECHNICAL FIELD

Embodiments relate to a polishing pad for use in a chemical mechanical planarization (CMP) process of semiconductors, a process for preparing the same, and a process for preparing a semiconductor device using the same.

### Background Art

The chemical mechanical planarization (CMP) process in a process for preparing semiconductors refers to a step in which a semiconductor substrate such as a wafer is fixed to a head and in contact with the surface of a polishing pad mounted on a platen, and the wafer is then chemically treated by supplying a slurry while the platen and the head are relatively moved, to thereby mechanically planarize the irregularities on the semiconductor substrate.

A polishing pad is an essential member that plays an important role in such a CMP process. In general, a polishing pad is composed of a polyurethane-based resin and has grooves on its surface for a large flow of a slurry and pores for supporting a fine flow thereof.

The pores in a polishing pad may be formed by using a solid phase foaming agent having voids, a liquid phase foaming agent filled with a volatile liquid, a gas phase foaming agent such as an inert gas, or the like, or by generating a gas by a chemical reaction.

However, the method of using a gas phase or volatile liquid phase foaming agent to form micropores in a polishing pad has the advantage that no material that may affect the CMP process is discharged, whereas there is a problem that it is difficult to precisely control the size, size distribution, and amount of pores. In addition, since the micropores each do not have a separate outer wall, it is difficult to maintain the shape of the micropores during the CMP process.

Meanwhile, the method of preparing a polishing pad using a solid phase foaming agent having an outer wall and a void has the advantage that the shape, size distribution, and amount of pores can be precisely controlled unlike the method of using a gas phase or volatile liquid phase foaming agent. It is advantageous that the shape of micropores can be maintained during the CMP process by virtue of the presence of the outer wall of the solid phase foaming agent.

However, when a solid phase foaming agent has a small size of a millimeter or less, the density of the solid phase foaming agent is extremely low because it is in the form of a hollow in which a polymer constitutes its outer periphery, resulting in a phenomenon that adjacent solid phase foaming agents coalesce with each other. If coalescence takes place, the pressure thereof gives rise to the phenomenon that the shape of some solid phase foaming agents cannot be maintained. In addition, while the solid phase foaming agent is transported and stored, there may be a phenomenon that the shape thereof is not maintained. In general, an anti-coalescence agent is coated in the process of preparing a solid phase foaming agent to prevent such coalescence, but it is difficult to completely control the coalescence phenomenon.

Thus, in the method of using a solid phase foaming agent, there is a limit to uniformly controlling the shape of the solid phase foaming agent, and there is a problem in that a solid phase foaming agent may partially coalesce in the polishing pad during the process in which the solid phase foaming agent is mixed to a polymer.

The shape of micropores and the pore coalescence phenomenon that partially takes place in a polishing pad may have an impact on the polishing rate (or removal rate), wafer planarization of a semiconductor substrate, and such defects as scratches and chatter marks among the significant performance of a CMP process. Thus, their control is particularly important.

### PRIOR ART DOCUMENT

### Patent Document

(Patent Document 1) Korean Patent No. 10-0418648

### DETAILED DESCRIPTION OF THE INVENTION

### Technical Problem

The present invention aims to solve the above problems of the prior art.

The technical problem to be solved in the present invention is to provide a polishing pad in which the shape of the micropores and the pore coalescence phenomenon in the polishing pad are controlled to adjust the sphericity of the pore structure and the volume ratio thereof, thereby enhancing the polishing characteristics, a process for preparing the same, and a process for preparing a semiconductor device using the same.

### Solution to the Problem

In order to accomplish the above object, an embodiment provides a polishing pad, which comprises a plurality of pores, wherein the average diameter (Dₐ) of the plurality of pores is, and the volume of pores having a sphericity of 0.2 to 0.9 according to the following Equation 1 is 50% by volume to 100% by volume based on the total volume of the plurality of pores:

$$Sphericity = \frac{{{π}^{\frac{1}{3}} ( 6 {V}_{pore} )}^{\frac{2}{3}}}{{A}_{pore}} \qquad [ Equation 1 ]$$

In Equation 1, Aₚₒᵣₑ is the cross-sectional area of pores, and Vₚₒᵣₑ is the volume of pores.

Another embodiment provides a process for preparing a polishing pad, which comprises mixing a urethane-based prepolymer, a solid phase foaming agent, and a curing agent to prepare a raw material mixture; and injecting the raw material mixture into a mold and molding it, wherein the polishing pad comprises a plurality of pores, the average diameter (Dₐ) of the plurality of pores is 5 μm to 200 μm, and the volume of pores having a sphericity of 0.2 to 0.9 according to the above Equation 1 is 50% by volume to 100% by volume based on the total volume of the plurality of pores.

Another embodiment provides a process for preparing a semiconductor device, which comprises mounting a polishing pad comprising a polishing layer comprising a plurality of pores on a platen; and relatively rotating the polishing pad and a semiconductor substrate while a polishing surface of the polishing layer and a surface of the semiconductor substrate are in contact with each other to polish the surface of the semiconductor substrate wherein the polishing pad comprises a plurality of pores, the average diameter (Dₐ) of the plurality of pores is 5 μm to 200 μm, and the volume of pores having a sphericity of 0.2 to 0.9 according to the following Equation 1 is 50% by volume to 100% by volume based on the total volume of the plurality of pores.

### Advantageous Effects of the Invention

According to the embodiment, it is possible to provide a polishing pad in which the average diameter of the plurality of pores contained in the polishing pad, the sphericity of the plurality of pores, and the volume ratio thereof are adjusted, thereby enhancing the polishing speed and reducing such surface defects as scratches and chatter marks appearing on the surface of a semiconductor substrate, a process for preparing the same, and a process for preparing a semiconductor device using the same.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a chart showing the relationship between general roundness and sphericity.

FIG. 2 is a schematic diagram illustrating the shape and sphericity (S1, S2) of two or more pores coalesced and uncoalesced in a plurality of pores.

FIG. 3 is a cross-sectional image obtained by a 3D CT-scan of the polishing pad of Comparative Example 1.

FIG. 4 is a cross-sectional image obtained by a 3D CT-scan of the polishing pad of Example 1 of the present invention.

FIG. 5 is a graph showing the sphericity with respect to the diameters of a plurality of pores in the polishing pad prepared in Example 1.

FIG. 6 is a graph showing the sphericity with respect to the diameters of a plurality of pores in the polishing pad prepared in Example 2.

FIG. 7 is a graph showing the sphericity with respect to the diameters of a plurality of pores in the polishing pad prepared in Example 3.

FIG. 8 is a graph showing the sphericity with respect to the diameters of a plurality of pores in the polishing pad prepared in Comparative Example 1.

FIG. 9 is a schematic diagram showing the classification unit in the classification and purification apparatus for a solid phase foaming agent according to an embodiment.

FIG. 10 is a diagram illustrating an operation state of the classification unit in the classification and purification apparatus for a solid phase foaming agent according to an embodiment.

FIG. 11 is an exploded perspective view of the filter unit (30a) in the classification and purification apparatus for a solid phase foaming agent according to an embodiment.

FIG. 12 schematically illustrates a process for preparing a semiconductor device according to an embodiment.

FIG. 13 is a photograph showing the shape of a scratch on a wafer according to an embodiment.

FIG. 14 is a photograph showing the shape of a chatter mark on a wafer according to an embodiment.

### BEST MODE FOR CARRYING OUT THE INVENTION

### Description of Terms

Unless otherwise stated or defined, all technical and scientific terms used herein have the same meaning as commonly understood by one of ordinary skill in the art to which this invention pertains.

Unless otherwise stated, all percentages, parts, and ratios are by weight.

All numerical ranges related to the quantities of components, physical properties such as molecular weight, reaction conditions, and the like used herein in all circumstances are to be understood as being modified by the term “about.”

In this specification, when a part is referred to as “comprising” an element, it is to be understood that it may comprise other elements as well, rather than excluding the other elements, unless specifically stated otherwise.

The term “plurality of” as used herein refers to more than one.

The term “D50” as used herein refers to the volume fraction of the 50th percentile (median) of a particle size distribution.

Hereinafter, the present invention is explained in detail by the following embodiments. The embodiments can be modified into various forms as long as the gist of the invention is not changed.

Polishing Pad

The polishing pad according to an embodiment comprises a plurality of pores, wherein the average diameter (Dₐ) of the plurality of pores is 5 μm to 200 μm, and the volume of pores having a sphericity of 0.2 to 0.9 according to the following Equation 1 is 50% by volume to 100% by volume based on the total volume of the plurality of pores.

$$Sphericity = \frac{{{π}^{\frac{1}{3}} ( 6 {V}_{pore} )}^{\frac{2}{3}}}{{A}_{pore}} \qquad [ Equation 1 ]$$

In Equation 1, Aₚₒᵣₑ is the cross-sectional area of pores, and Vₚₒᵣₑ is the volume of pores.

In the present specification, the “sphericity” refers to the degree of retaining the spherical shape of each pore, which is calculated according to the above Equation 1 using a 3D CT-scan (GE Corporation).

Specifically, the polishing pad may have a Dₐ of 7 μm to 100 μm, and the volume of pores having a sphericity of 0.2 to 0.9 may be 60% by volume to 100% by volume based on the total volume of the plurality of pores.

The “cross-sectional area of pores” in the denominator of Equation 1 is calculated using the data in the form of voxels obtained by 3D-CT-scan. A voxel is a set of graphic information defining a point in a 3D space. Since a pixel defines a point in a 2D space with x-y coordinates, a third z coordinate is required. Each coordinate represents a location, color, and density in 3D. With this information and 3D software, it is possible to create 2D screens from various angles. It is used for CT scan, oil exploration, CAD, and the like since the internal condition can be known therefrom.

Specifically, based on the unit area of a polishing pad (1 mm²), it is possible to measure the pores inside the polishing pad by a 3D CT-scan, and the CT data analysis and visualization software called Volume Graphics may be used to calculate the sphericity, diameter, area, and volume of the pores.

For example, in Equation 1, when the pore diameter is r, Aₚₒᵣₑ is calculated as πr², Vₚₒᵣₑ=4/3πr³, and Da is calculated as the number average value of the pore diameters.

According to an embodiment, the average diameter of the plurality of pores may be 5 μm to 200 μm, specifically 7 μm to 100 μm, more specifically 10 μm to 50 μm.

Meanwhile, when a solid phase foaming agent is mixed to a polymer in the preparation of a polishing pad, it may be partially aggregated in the polishing pad, which may result in partial coalescence of pores in the polishing pad. This coalescence phenomenon can be confirmed by plotting the diameter and sphericity of the pores through a 3D CT-scan of the polishing pad.

In this regard, FIG. 1 is a chart showing the relationship between roundness and sphericity. In the present specification, the roundness is a value measured based on a flat standard, that is, 2D, to the extent that it becomes round like a circle, and the sphericity is a value measured based on a three-dimensional standard, that is, 3D, to the extent that it becomes round like a ball. As illustrated in FIG. 1, the higher the values of the roundness and sphericity, the closer to a sphere. That is, in FIG. 1, when the roundness is 0.9 and the sphericity is 0.9, it may mean the closest to a sphere.

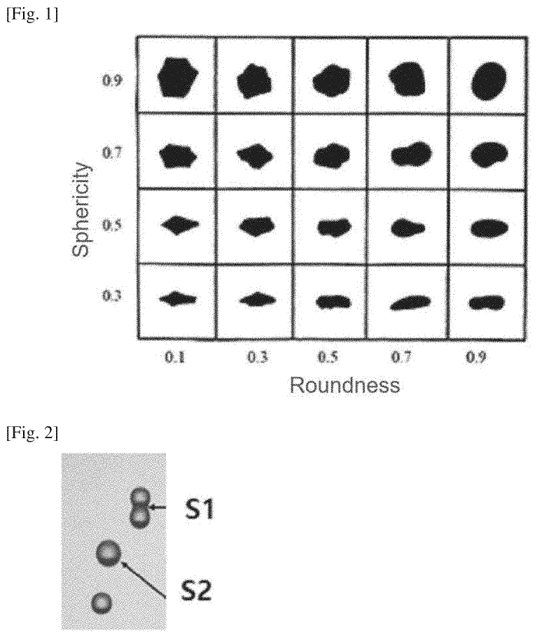

However, when a plurality of pores are present as aggregated, as shown in FIG. 2, the lower the sphericity, the greater the coalescence phenomenon; and the higher the sphericity, the less the coalescence phenomenon. For example, in FIG. 2, S1, which stands for the sphericity when two or more pores coalesce, is 0.5051, and S2, which is the sphericity when no pores coalesce, is 0.9660. However, FIGS. 1 and 2 are exemplary for defining the sphericity, but it is not limited thereto.

According to an embodiment of the present invention, the sphericity of a plurality of pores is controlled, whereby it is possible to adjust the shape and coalescence phenomenon of the pores, thereby enhancing the polishing speed of the polishing pad and minimizing such surface defects as scratches and chatter marks appearing on the surface of a semiconductor substrate. The flowability of a polishing slurry and the polishing efficiency hinge on the sphericity and volume ratio of the pores exposed on the surface of a polishing pad.

That is, the flowability of a polishing slurry is affected by the sphericity of the pores exposed on the surface of the polishing pad, which determines the occurrence of scratches and chatter marks on the surface of an object to be polished and the polishing rate. In the polishing pad according to an embodiment, the sphericity of the plurality of pores is controlled to an appropriate range, which may be designed as a volume percentage of an appropriate range based on the total volume of the plurality of pores. As a result, it is possible to reduce such surface defects as scratches and chatter marks on the surface of an object to be polished and to achieve excellent polishing efficiency. In particular, it is possible to enhance the polishing characteristics while using a solid phase foaming agent alone without the use of a liquid phase foaming agent or a gas phase foaming agent.

In the polishing pad according to an embodiment, the volume of pores having a sphericity of 0.2 to 0.9 according to the above Equation 1 may be 50% by volume to 100% by volume, specifically 60% by volume to 100% by volume, more specifically 63% by volume to 100% by volume, based on the total volume of the plurality of pores. If it is designed to have a volume ratio of the sphericity within the above range, the polishing pad of the present invention can improve the polishing speed and minimize such surface defects as scratches and chatter marks on the surface of an object to be polished. If the volume of pores having a sphericity of the above range is less than the above volume percentage, the polishing speed may be decreased, and the occurrence of such surface defects as scratches and chatter marks may be increased.

The plurality of pores may have a sphericity of 0.001 to less than 1.0, specifically 0.002 to 0.9, more specifically 0.004 to 0.9.

In addition, the plurality of pores may comprise one or more pores selected from first pores having a sphericity of 0.001 to less than 0.2 and second pores having a sphericity of 0.2 to less than 1.0.

According to an embodiment of the present invention, the total volume of the second pores may be greater than the total volume of the first pores.

According to another embodiment of the present invention, the polishing layer may not comprise the first pores. For example, the second pores may be contained in an amount of 100% by volume based on the total volume of the plurality of pores. In such case, it is possible to remarkably improve the polishing speed and to remarkably reduce the occurrence of such surface defects as scratches and chatter marks appearing on the surface of a wafer.

In addition, the polishing pad may have an average diameter (Dₐ) of the plurality of pores of 5 μm to 200 μm, specifically 7 μm to 100 μm, more specifically 10 μm to 50 μm. The Dₐ refers to the arithmetic average diameter of the plurality of pores within 1 mm of the polished surface. It may be calculated by performing CT-scan and measuring the pore diameters of the respective pores observed within 1 mm² of the polishing surface using the Volume Graphics software.

In the polishing pad according to an embodiment, the flowability of a polishing slurry and the polishing efficiency hinge on the diameters of the pores exposed on the surface thereof. If the Dₐ is less than the above range, the pore diameter is too small, thereby reducing the flowability of a slurry, which may increase the occurrence of defects.

Physical Properties of the Polishing Pad

As described above, in the polishing pad according to an embodiment, if the average diameter (Dₐ) of the plurality of pores is 5 μm to 200 μm, and the volume of pores having a sphericity of 0.2 to 0.9 is 50% by volume to 100% by volume based on the total volume of the plurality of pores, the polishing speed of the polishing pad and the physical properties of the polishing pad are significantly enhanced.

The polishing pad may have grooves on its surface for mechanical polishing. The grooves may have a depth, a width, and a spacing as desired for mechanical polishing, which are not particularly limited.

Process for Preparing a Polishing Pad

According to an embodiment, there is provided a process for preparing a polishing pad, which comprises mixing a urethane-based prepolymer, a solid phase foaming agent, and a curing agent to prepare a raw material mixture; and injecting the raw material mixture into a mold and molding it, wherein the polishing pad comprises a plurality of pores, the average diameter (Dₐ) of the plurality of pores is 5 μm to 200 μm, and the volume of pores having a sphericity of 0.2 to 0.9 according to the following Equation 1 is 50% by volume to 100% by volume based on the total volume of the plurality of pores.

Specifically, the raw material mixture may comprise 55 to 96.5 parts by weight of the urethane-based prepolymer, 0.5 to 5.0 parts by weight of the solid phase foaming agent, and 3.0 to 40 parts by weight of the curing agent based on 100 parts by weight of the raw material mixture. More specifically, the raw material mixture may comprise 66.5 to 96.5 parts by weight of the urethane-based prepolymer, 0.5 to 3.5 parts by weight of the solid phase foaming agent, and 5.0 to 35 parts by weight of the curing agent based on 100 parts by weight of the raw material mixture.

Urethane-Based Prepolymer

The urethane-based prepolymer may be prepared by reacting an isocyanate compound with a polyol.

A prepolymer generally refers to a polymer having a relatively low molecular weight wherein the degree of polymerization is adjusted to an intermediate level for the sake of conveniently molding a product in the process of producing the same. A prepolymer may be molded by itself or after a reaction with another polymerizable compound. For example, a prepolymer may be prepared by reacting an isocyanate compound with a polyol.

For example, the isocyanate compound that may be used in the preparation of the urethane-based prepolymer may be at least one isocyanate selected from the group consisting of toluene diisocyanate (TDI), naphthalene-1,5-diisocyanate, p-phenylene diisocyanate, tolidine diisocyanate, 4,4′-diphenylmethane diisocyanate, hexamethylene diisocyanate, dicyclohexylmethane diisocyanate, and isophorone diisocyanate. But it is not limited thereto.

For example, the polyol that may be used in the preparation of the urethane-based prepolymer may be at least one polyol selected from the group consisting of a polyether polyol, a polyester polyol, a polycarbonate polyol, and an acryl polyol. But it is not limited thereto. The polyol may have a weight average molecular weight (Mw) of 300 g/mole to 3,000 g/mole.

The urethane-based prepolymer may have a weight average molecular weight of 500 g/mole to 3,000 g/mole. Specifically, the urethane-based prepolymer may have a weight average molecular weight (Mw) of 600 g/mole to 2,000 g/mole or 800 g/mole to 1,000 g/mole.

As an example, the urethane-based prepolymer may be a polymer having a weight average molecular weight (Mw) of 500 g/mole to 3,000 g/mole, which is polymerized from toluene diisocyanate as an isocyanate compound and polytetramethylene ether glycol as a polyol.

Solid Phase Foaming Agent

The plurality of pores in the polishing pad according to an embodiment of the present invention may be derived from a solid phase foaming agent. In addition, the solid phase foaming agent may be purified by a purification system, through which a solid phase foaming agent having a uniform density or average particle diameter can be collected and purified.

For example, the average particle diameter (D50) of the solid phase foaming agent thus purified may be 5 μm to 200 μm. Here, the term D50 may refer to the volume fraction of the 50^{th} percentile (median) in a particle diameter distribution. More specifically, the solid phase foaming agent may have a D50 of 7 μm to 100 μm. Even more specifically, the solid phase foaming agent may have a D50 of 10 μm to 50 μm; 15 μm to 45 μm; or 20 μm to 40 μm. The purification system for a solid phase foaming agent may filter out the solid phase foaming agent having an average particle diameter that is too small or too large to satisfy the average particle diameter of the above range. It is possible to selectively control the average particle diameter of the solid phase foaming agent in the above range according to the required purpose.

If the D50 of the solid phase foaming agent satisfies the above range, the polishing rate and within-wafer non-uniformity can be further enhanced. If the D50 of the solid phase foaming agent is less than the above range, the number average diameter of pores is decreased, which may have an impact on the polishing rate and within-wafer non-uniformity. If it exceeds the above range, the number average diameter of pores is excessively increased, which may have an impact on the polishing rate and within-wafer non-uniformity.

In addition, the standard deviation of the average particle diameter of the solid phase foaming agent may be 12 or less, specifically 10 or less, more specifically 9.9 or less.

If a solid phase foaming agent purified by the purification system as described above is used, the average diameter of the plurality of pores contained in the polishing pad, as well as the sphericity of the plurality of pores and the volume ratio thereof can be adjusted.

The solid phase foaming agent is thermally expanded (i.e., size-controlled) microcapsules and may be in a structure of micro-balloons having an average pore size of 5 μm to 200 μm. The thermally expanded (i.e., size-controlled) microcapsules may be obtained by thermally expanding thermally expandable microcapsules.

The thermally expandable microcapsule may comprise a shell comprising a thermoplastic resin; and a foaming agent encapsulated inside the shell. The thermoplastic resin may be at least one selected from the group consisting of a vinylidene chloride-based copolymer, an acrylonitrile-based copolymer, a methacrylonitrile-based copolymer, and an acrylic-based copolymer. Further, the foaming agent encapsulated in the inside may be at least one selected from the group consisting of hydrocarbons having 1 to 7 carbon atoms. Specifically, the foaming agent encapsulated in the inside may be selected from the group consisting of a low molecular weight hydrocarbon such as ethane, ethylene, propane, propene, n-butane, isobutane, butene, isobutene, n-pentane, isopentane, neopentane, n-hexane, heptane, petroleum ether, and the like; a chlorofluorohydrocarbon such as trichlorofluoromethane (CCl₃F), dichlorodifluoromethane (CCl₂F₂), chlorotrifluoromethane (CClF₃), tetrafluoroethylene (CClF₂—CClF₂), and the like; and a tetraalkylsilane such as tetramethylsilane, trimethylethylsilane, trimethylisopropylsilane, trimethyl-n-propylsilane, and the like.

The solid phase foaming agent may be employed in an amount of 0.5 part by weight to 5.0 parts by weight based on 100 parts by weight of the raw material mixture. Specifically, the solid phase foaming agent may be employed in an amount of 0.5 part by weight to 3.5 parts by weight based on 100 parts by weight of the raw material mixture. Alternatively, the solid phase foaming agent may be employed in an amount of 0.5 part by weight to 3.0 parts by weight based on 100 parts by weight of the raw material mixture. Alternatively, the solid phase foaming agent may be employed in an amount of 0.5 part by weight to 2.0 parts by weight. Alternatively, the solid phase foaming agent may be employed in an amount of 0.5 parts by weight to 1.5 part by weight, or 0.8 part by weight to 1.4 parts by weight, based on 100 parts by weight of the raw material mixture.

The purification system for a solid phase foaming agent will be described in detail in the following section.

Purification System for the Solid Phase Foaming Agent

Various purification systems may be used as the purification system for a solid phase foaming agent as long as they can achieve the average particle diameter (D50) of the solid phase foaming agent in the above range and satisfy the sphericity desired in the present invention.

According to an embodiment of the present invention, a classification and purification apparatus for a solid phase foaming agent is used as the purification system for a solid phase foaming agent.

The classification and purification apparatus for a solid phase foaming agent according to an embodiment comprises a classification unit for classifying a supplied solid foaming agent into first microspheres and second microspheres, a storage unit connected to the classification unit in which the classified first microspheres are introduced, stored, and discharged, and a filter unit disposed in the moving path of the solid phase foaming agent or the first microspheres to separate metallic materials from the object to be filtered that comprises the solid phase foaming agent or the first microspheres.

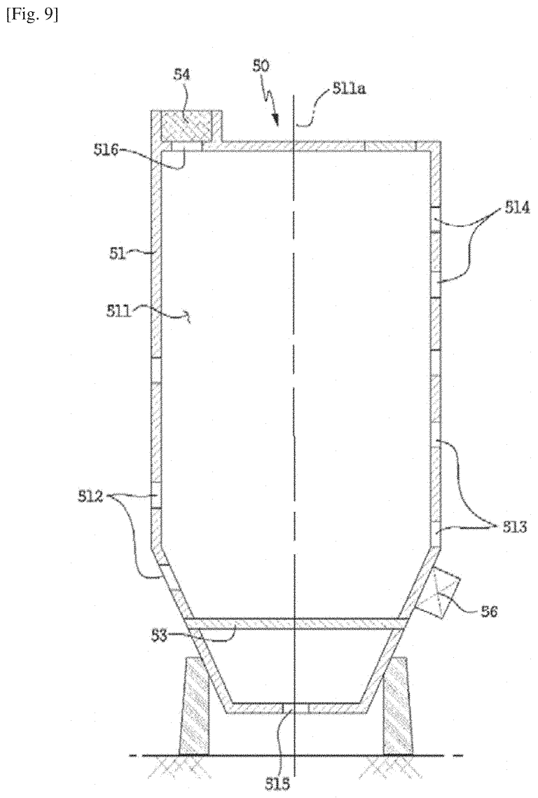

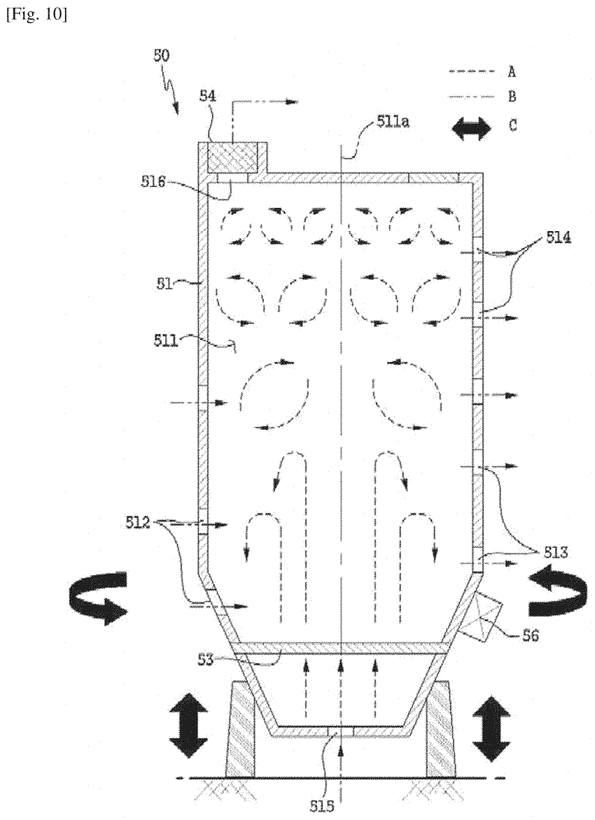

FIG. 9 is a schematic diagram showing the classification unit according to an embodiment. FIG. 10 is a diagram illustrating an operation state of the classification unit of FIG. 9.

Referring to FIGS. 9 and 10, the classification unit (50) comprises a classification housing (51) having a classification space (511) formed therein, a gas supply hole (515) connected to the classification space (511), and a classification discharge hole connected to the classification space (511). The classification unit (50) may further comprise a vortex generating member (53) positioned in the classification space (511) and disposed adjacent to the gas supply hole (515). The classification unit (50) may further comprise a vibration generating unit (56) disposed in the classification housing (51). The classification unit (50) may further comprise a classifying and stirring unit.

Classification of the solid phase foaming agent introduced into the classification space (511) through any of the classification inlet holes (512) may be performed as follows. In the classification space (511), a fluidizing gas is supplied to classify the solid phase foaming agent. The fluidizing gas introduced into the classification space (511) flows in the direction of the gas discharge hole (516) while it passes through the vortex generating member (53). In such event, the fluidizing gas flows while it generates rotation or vortexes (dashed arrow in the classification space (511) of FIG. 10: marked as A). The fluidizing gas flows to the top where the gas discharge hole (516) is located. The solid phase foaming agent introduced into the classification space (511) rises along the fluidizing gas that is flowing and then falls within the classification space (511) promoted by a downward flow generated as the flow of the fluidizing gas is weakened or by rotational force, vibration, or the like transmitted from the outside (in FIG. 10, the flow of the solid phase foaming agent is indicated by a double-dashed line arrow: B, and a vibration arrow: C). In such event, the flow of air in the classification space (511) forms a circulating flow of air cells, so that when the particles of the solid phase foaming agent are heavy or too light relative to their size or when the shape of the particles is remarkably different, the rising or falling speed thereof varies so that they are classified. That is, the solid phase foaming agent is fluidized in the classification space (511) with the flow of the fluidizing gas, and the solid phase foaming agent falls at different speeds according to its weight and size under the influence of gravity, vibration, and the like, so that it can be classified and recovered according to the size.

The solid phase foaming agent rising or falling under the influence of the fluidizing gas as described above may be discharged outside the classification housing (51) through first microsphere discharge holes (513) and second microsphere discharge holes (514) formed according to the height of the classification housing (51), respectively.

A gas discharge hole (516) through which the fluidizing gas introduced into the classification space (511) is discharged may be formed on the top side of the classification housing (51). A discharge filter (54) for filtering foreign matters, residual microspheres, and the like contained in the discharged fluidizing gas is disposed in the gas discharge hole (516).

In an embodiment, the vibration process may be performed as a vertical vibration that moves up and down around the central axis (511a) to the classification housing (51) through the vibration generating unit (56), a horizontal vibration that moves left and right, or a vertical and horizontal vibration applied in both the vertical and horizontal directions sequentially or simultaneously. In addition, the vibration process may be performed by rotating the classification housing (51) clockwise or counterclockwise with respect to the central axis (550) or repeating the rotation in clockwise and counterclockwise directions. For example, the vibration applied in the vibration process may be a vibration of 100 to 10,000 Hz, for example, a vibration of 500 to 5,000 Hz, for example, a vibration of 700 to 3,500 Hz. When a vibration within the above range is applied, the solid phase foaming agent can be more efficiently classified.

Due to the characteristics of a relatively small and light solid phase foaming agent, it can be classified by the difference in the rising and falling speeds of the solid phase foaming agent with the flow of the fluidizing gas, whereas the hollow microspheres, which rise by the fluidizing gas but hardly fall, can readily fall by the vibration. That is, the vibration process may be carried out in a manner of a down force vibration that promotes the falling of the solid phase foaming agent in the classification space (511). If the vibration process proceeds further, more efficient and effective classification can be performed. The polishing layer formed through this process can provide a semiconductor substrate with fewer defects.

The particle diameter of the classified solid phase foaming agent may be adjusted by the flow rate of the injected fluidizing gas, the position of the first microsphere discharge hole (513), the degree of vibration, and the like. As a result, the solid phase foaming agent may be classified into first microspheres having an average particle diameter of about 5 μm to about 200 μm and second microspheres having an average particle diameter of less than about 5 μm. The solid phase foaming agent that is damaged or has too high a density may be the third microspheres. Thus, the solid phase foaming agent may be classified into first to third microspheres in the classification space (511). The particle size of the classified solid phase foaming agent may hinge upon the design of the polishing pad.

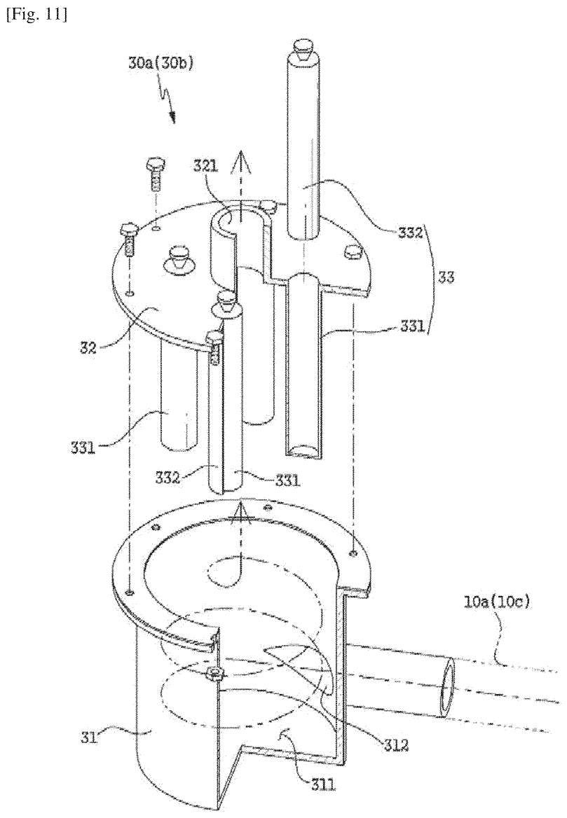

FIG. 11 is an exploded perspective view of the filter unit (30a and 30b) according to an embodiment. Referring to FIGS. 9 and 11, the filter units (30a and 30b) may be disposed at the front end, the rear end, or the front and rear ends of the classification unit. The filter unit (30b) disposed at the rear end of the classification unit may remove metal components in the first microspheres separated through the classification space (511). The filter unit (30a) disposed at the front end of the classification unit may remove metal components from the solid phase foaming agent before it is introduced to the classification unit (50).

Referring to FIG. 11, the filter unit (30a) comprises a filter housing (31) having a filter space (311) therein through which the solid phase foaming agent passes through, a filter cover (32) detachably disposed to the filter housing (31) to open and close the filter space (311), and a filter member (33) disposed in the filter space (311) and generating magnetic force.

A filter inlet (312) connected to the pipes (10a and 10c) may be formed in the filter housing (31). The solid phase foaming agent is introduced into the filter space (311) through the filter inlet (312) and may move in an open direction while rotating along the circumference of the filter space (311). The filter member (33) is located in the filter space (311), which may induce the generation of vortexes in the flow of the solid phase foaming agent.

In an embodiment, a filter outlet (321) connected to the filter space (311) may be formed in the filter cover (32). In another embodiment, the filter outlet (321) may be formed in the periphery of the filter housing (31). The location of the filter outlet (321) may vary with the type or density of the object to be filtered. The solid phase foaming agent passing through the filter space (311) through the filter inlet (312) may be discharged to the outside of the filter housing (31) through the filter outlet (321).

The filter member (33) may comprise a mounting member (331) positioned in the filter space (311) and a magnet (332) disposed in the mounting member (331). In an embodiment, the magnet (332) may be disposed inside the mounting member (331). The magnet (332) may comprise a paramagnet or an electromagnet. The magnet may be a neodymium magnet. The magnet may have a magnetic force of 10,000 Gauss to 12,000 Gauss. The magnet generates a magnetic field around the mounting member (331), and a metallic material adheres to the magnet. The metallic material contained in the solid phase foaming agent that rotates in the filter space (311) may adhere to the outer periphery of the mounting member (331) by the magnetic force. The metallic material mixed with the object to be filtered that passes through the filter space (311) may be separated by the magnet (332). A purified solid phase foaming agent or first microspheres may be provided through the filter unit.

As the solid phase foaming agent is processed through the classification unit, the performance of roughness control in the surface processing of a polishing pad prepared using the same may be enhanced. If the size of the solid phase foaming agent is too small, the composition for preparing a polishing pad may aggregate. If the size of the solid phase foaming agent is too large, it is difficult to control the pore size, thereby deteriorating the surface characteristics of the polishing pad. Therefore, as a solid phase foaming agent of an appropriate size is provided through the classification unit, it is possible to prevent the composition for preparing a polishing pad from aggregating. Furthermore, the roughness characteristics with a uniform and suitable depth/width on the surface of a polishing pad can be achieved.

In addition, the metallic foreign matters with high density in the solid phase foaming agent and the aggregates formed therefrom as a seed, and the like affect the surface condition of a polishing pad and act as an obstacle to processing the desired level of roughness characteristics. Thus, the use of the solid phase foaming agent from which metal components have been removed through the filter unit can minimize the foreign matters with high density and the aggregates to be contained in the polishing pad. As a result, it is possible to secure an effect of enhancing the quality, such as remarkably reduced defects of products such as semiconductor substrates polished with a polishing pad having excellent surface characteristics.

Curing Agent

The curing agent may be at least one of an amine compound and an alcohol compound. Specifically, the curing agent may comprise at least one compound selected from the group consisting of an aromatic amine, an aliphatic amine, an aromatic alcohol, and an aliphatic alcohol.

For example, the curing agent may be at least one selected from the group consisting of 4,4′-methylenebis(2-chloroaniline) (MOCA), diethyltoluenediamine, diaminodiphenylmethane, diaminodiphenyl sulphone, m-xylylenediamine, isophoronediamine, ethylenediamine, diethylenetriamine, triethylenetetramine, polypropylenediamine, polypropylenetriamine, ethylene glycol, diethylene glycol, dipropylene glycol, butanediol, hexanediol, glycerin, trimethylolpropane, and bis(4-amino-3-chlorophenyl)methane.

The urethane-based prepolymer and the curing agent may be mixed at a molar equivalent ratio of 1:0.8 to 1:1.2, or a molar equivalent ratio of 1:0.9 to 1:1.1, based on the number of moles of the reactive groups in each molecule. Here, “the number of moles of the reactive groups in each molecule” refers to, for example, the number of moles of the isocyanate group in the urethane-based prepolymer and the number of moles of the reactive groups (e.g., amine group, alcohol group, and the like) in the curing agent. Therefore, the urethane-based prepolymer and the curing agent may be fed at a constant rate during the mixing process by controlling the feeding rate such that the urethane-based prepolymer and the curing agent are fed in amounts per unit time that satisfies the molar equivalent ratio exemplified above.

The curing agent may be employed in an amount of 3.0 parts by weight to 40 parts by weight based on 100 parts by weight of the raw material mixture. Specifically, the curing agent may be employed in an amount of 5.0 parts by weight to 35 parts by weight based on 100 parts by weight of the raw material mixture. Specifically, the curing agent may be employed in an amount of 7.0 parts by weight to 30 parts by weight based on 100 parts by weight of the raw material mixture.

Surfactant

The raw material mixture may further comprise a surfactant. The surfactant may act to prevent the pores to be formed from overlapping and coalescing with each other. Specifically, the surfactant is preferably a silicone-based nonionic surfactant. But other surfactants may be variously selected depending on the physical properties required for the polishing pad.

As the silicone-based nonionic surfactant, a silicone-based nonionic surfactant having a hydroxyl group may be used alone or in combination with a silicone-based nonionic surfactant having no hydroxyl group.

The silicone-based nonionic surfactant having a hydroxyl group is not particularly limited as long as it is widely used in the polyurethane technology industry since it is excellent in compatibility with an isocyanate-containing compound and an active hydrogen compound. Examples of the silicone-based nonionic surfactant having a hydroxyl group, which is commercially available, include DOW CORNING 193 (a silicone glycol copolymer in a liquid phase having a specific gravity at 25° C. of 1.07, a viscosity at 20° C. of 465 mm²/s, and a flash point of 92° C.)(hereinafter referred to as DC-193) manufactured by Dow Corning.

Examples of the silicone-based nonionic surfactant having no hydroxyl group, which is commercially available, include DOW CORNING 190 (a silicone glycol copolymer having a Gardner color number of 2, a specific gravity at 25° C. of 1.037, a viscosity at 25° C. of 2,000 mm²/s, a flash point of 63° C. or higher, and an inverse solubility point (1.0% water solution) of 36° C. (hereinafter referred to as DC-190) manufactured by Dow Corning.

The surfactant may be employed in an amount of 0.1 to 2 parts by weight based on 100 parts by weight of the raw material mixture. Specifically, the surfactant may be employed in an amount of 0.2 to 1.8 parts by weight, 0.2 to 1.7 parts by weight, 0.2 to 1.6 parts by weight, or 0.2 to 1.5 parts by weight, based on 100 parts by weight of the raw material mixture. If the amount of the surfactant is within the above range, pores derived from the gas phase foaming agent can be stably formed and maintained in the mold.

Reaction and Formation of Pores

The urethane-based prepolymer and the curing agent react with each other upon the mixing thereof to form a solid polyurethane, which is then formed into a sheet or the like. Specifically, the isocyanate terminal group in the urethane-based prepolymer can react with the amine group, the alcohol group, and the like in the curing agent. In such event, the solid phase foaming agents are uniformly dispersed in the raw materials to form pores without participating in the reaction between the urethane-based prepolymer and the curing agent.

Molding

The molding is carried out using a mold. Specifically, the raw materials sufficiently stirred in a mixing head or the like may be injected into a mold to fill the inside thereof.

Control of the sphericity of a plurality of pores contained in the polishing pad according to an embodiment of the present invention may be performed using the rotational speed of the mixing head and the purification system for a solid phase foaming agent. Specifically, in the process of mixing and dispersing the urethane-based prepolymer, the solid phase foaming agent, and the curing agent, they are mixed by, for example, a mixing system at a rotational speed of the mixing head of for example, 500 rpm to 10,000 rpm, specifically 700 rpm to 9,000 rpm, 900 rpm to 8,000 rpm, 1,000 to 5,000 rpm, or 2,000 to 5,000 rpm. Alternatively, in the process of mixing and dispersing the urethane-based prepolymer, the solid phase foaming agent, and the curing agent, the solid phase foaming agent purified by the purification system may be used.

The reaction between the urethane-based prepolymer and the curing agent is completed in the mold to thereby produce a molded body in the form of a solidified cake that conforms to the shape of the mold.

Thereafter, the molded body thus obtained may be appropriately sliced or cut into a sheet for the production of a polishing pad. As an example, a molded body is prepared in a mold having a height of 5 to 50 times the thickness of a polishing pad to be finally produced and is then sliced in the same thickness to produce a plurality of sheets for the polishing pads at a time. In such event, a reaction retarder may be used as a reaction rate controlling agent in order to secure a sufficient solidification time. Thus, the height of the mold may be about 5 to about 50 times the thickness of the polishing pad to be finally produced to prepare sheets therefor. However, the sliced sheets may have pores of different diameters depending on the molded location inside the mold. That is, a sheet molded at the lower position of the mold has pores of a fine diameter, whereas a sheet molded at the upper position of the mold may have pores of a larger diameter than that of the sheet formed at the lower position.

Therefore, it is preferable to use a mold capable of producing one sheet by one molding in order for sheets to have pores of a uniform diameter with each other. To this end, the height of the mold may not significantly differ from the thickness of the polishing pad to be finally produced. For example, the molding may be carried out using a mold having a height of 1 to 3 times the thickness of the polishing pad to be finally produced. More specifically, the mold may have a height of 1.1 to 4.0 times, or 1.2 to 3.0 times, the thickness of the polishing pad to be finally produced. In such event, a reaction promoter may be used as the reaction rate controlling agent to form pores having a more uniform diameter. The polishing pad prepared from a single sheet may have a thickness of 1 mm to 10 mm. Specifically, the polishing pad may have a thickness of 1 mm to 9 mm, 1 mm to 8.5 mm, 1.5 mm to 10 mm, 1.5 mm to 9 mm, 1.5 mm to 8.5 mm, 1.8 mm to 10 mm, 1.8 mm to 9 mm, or 1.8 mm to 8.5 mm.

Thereafter, the top and bottom ends of the molded body obtained from the mold can be cut out, respectively. For example, each of the top and bottom ends of the molded body may be cut out by ⅓ or less, 1/22 to 3/10, or 1/12 to ¼ of the total thickness of the molded body.

As a specific example, the molding is carried out using a mold having a height of 1.2 to 2 times the thickness of the polishing pad to be finally produced, and a further step cutting out each of the top and bottom ends of the molded body obtained from the mold upon the molding by 1/12 to ¼ of the total thickness of the molded body may then be carried out.

Subsequent to the above cutting step, the above preparation process may further comprise the steps of machining grooves on the surface of the molded body, bonding with the lower part, inspection, packaging, and the like. These steps may be carried out in a conventional manner for preparing a polishing pad.

In addition, the polishing pad prepared by the preparation process as described above may have all of the characteristics of the polishing pad according to the embodiment as described above.

[Process for Preparing a Semiconductor Device]

The process for preparing a semiconductor device according to an embodiment comprises mounting a polishing pad comprising a polishing layer comprising a plurality of pores on a platen; and relatively rotating the polishing pad and a semiconductor substrate while a polishing surface of the polishing layer and a surface of the semiconductor substrate are in contact with each other to polish the surface of the semiconductor substrate wherein the polishing pad comprises a plurality of pores, the average diameter (Dₐ) of the plurality of pores is 5 μm to 200 μm, and the volume of pores having a sphericity of 0.2 to 0.9 according to the following Equation 1 is 50% by volume to 100% by volume based on the total volume of the plurality of pores.

$$Sphericity = \frac{{{π}^{\frac{1}{3}} ( 6 {V}_{pore} )}^{\frac{2}{3}}}{{A}_{pore}} \qquad [ Equation 1 ]$$

In Equation 1, Aₚₒᵣₑ, is the cross-sectional area of pores, and Vₚₒᵣₑ is the volume of pores.

The process for preparing a semiconductor device may comprise mounting a polishing pad comprising a polishing layer on a platen; and relatively rotating the polishing surface of the polishing layer and the surface of a semiconductor substrate while they are in contact with each other to polish the surface of the semiconductor substrate.

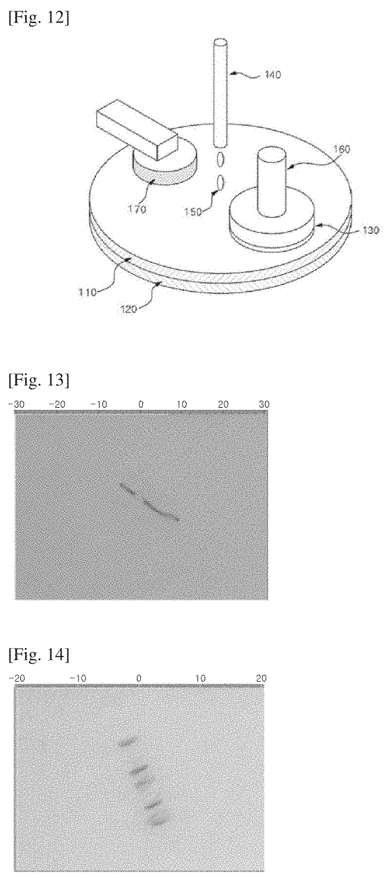

FIG. 12 schematically illustrates a process for preparing a semiconductor device according to an embodiment. Referring to FIG. 12, once the polishing pad (110) according to an embodiment is attached to a platen (120), a semiconductor substrate (130) is disposed on the polishing pad (110). In such event, the surface of the semiconductor substrate (130) is in direct contact with the polishing surface of the polishing pad (110). A polishing slurry (150) may be sprayed through a nozzle (140) on the polishing pad for polishing. The flow rate of the polishing slurry (150) supplied through the nozzle (140) may be selected according to the purpose within a range of about 10 cm³/min to about 1,000 cm³/min. For example, it may be about 50 cm³/min to about 500 cm³/min, but it is not limited thereto.

Thereafter, the semiconductor substrate (130) and the polishing pad (110) rotate relatively to each other, so that the surface of the semiconductor substrate (130) is polished. In such event, the rotation direction of the semiconductor substrate (130) and the rotation direction of the polishing pad (110) may be the same direction or opposite directions. The rotation speeds of the semiconductor substrate (130) and the polishing pad (110) may be selected according to the purpose within a range of about 10 rpm to about 500 rpm. For example, it may be about 30 rpm to about 200 rpm, but it is not limited thereto.

The semiconductor substrate (130) mounted on the polishing head (160) is pressed against the polishing surface of the polishing pad (110) at a predetermined load to be in contact therewith, the surface thereof may then be polished. The load applied to the polishing surface of the polishing pad (110) through the surface of the semiconductor substrate (130) by the polishing head (160) may be selected according to the purpose within a range of about 1 gf/cm² to about 1,000 gf/cm². For example, it may be about 10 gf/cm² to about 800 gf/cm², but it is not limited thereto.

In an embodiment, in order to maintain the polishing surface of the polishing pad (110) in a state suitable for polishing, the process for preparing a semiconductor device may further comprise processing the polishing surface of the polishing pad (110) with a conditioner (170) simultaneously with polishing the semiconductor substrate (130).

According to the embodiment, it is possible to provide a polishing pad in which the average diameter of the plurality of pores contained in the polishing pad, the sphericity of the plurality of pores, and the volume ratio thereof are adjusted, thereby enhancing the polishing speed and reducing such surface defects as scratches and chatter marks appearing on the surface of a semiconductor substrate. Thus, it is possible to efficiently fabricate a semiconductor device of excellent quality using the same.

### Embodiments for Carrying Out the Invention

Hereinafter, the present invention is explained in detail by the following Examples. However, these examples are set forth to illustrate the present invention, and the scope of the present invention is not limited thereto.

### EXAMPLE

Preparation Example: Preparation of a Urethane-Based Prepolymer

Toluene diisocyanate (TDI, BASF) as an isocyanate compound and polytetramethylene ether glycol (PTMEG, Korea PTG) as a polyol were mixed such that the content of the NCO group was 9.1% by weight and then reacted. In order to minimize side reactions during the synthesis, the inside of the reactor was filled with nitrogen (N₂) as an inert gas at a reaction temperature of 75° C. and stirred for 3 hours to carry out the reaction, thereby preparing a urethane-based prepolymer having a content of the NCO group of 9.1% by weight.

<Preparation of a Polishing Pad>

### Example 1

1-1: Configuration of the Device

Prepared were the urethane-based prepolymer obtained in the above preparation example, triethylenediamine (Dow) as a curing agent, and a solid phase foaming agent having a D50 of 25 μm and the characteristics of the second pores, which was obtained by purifying a microcapsule (Akzonobel) using the above-described purification system for the solid phase foaming agent (i.e., classification and purification apparatus for a solid phase foaming agent).

In a casting machine equipped with feeding lines for a urethane-based prepolymer, a curing agent, an inert gas, and a solid phase foaming agent, the urethane-based prepolymer prepared above was charged, the curing agent of triethylenediamine was charged to the curing agent tank, and the purified solid phase foaming agent was quantified in an amount of 2.0 parts by weight relative to 100 parts by weight of the raw material mixture and charged to the prepolymer tank at the same time.

1-2: Preparation of a Sheet

The urethane-based prepolymer and the curing agent were stirred while they were fed to the mixing head rotating at a speed of 3,000 rpm through the respective feeding lines. In such event, the molar equivalent ratio of the NCO group in the urethane-based prepolymer to the reactive groups in the curing agent was adjusted to 1:1, and the total feed rate was maintained at a rate of 10 kg/minute.

The mixed raw materials (i.e., raw material mixture) were injected into a mold (1,000 mm×1,000 mm×3 mm) and reacted to obtain a molded article in the form of a solid cake. Thereafter, the top and bottom of the molded body were each ground by a thickness of 0.5 mm to obtain an upper pad having a thickness of 2 mm.

Thereafter, the upper pad was subjected to surface milling and groove forming steps and laminated with a lower pad by a hot melt adhesive, thereby preparing a polishing pad. The polishing pad thus prepared had an average diameter (Dₐ) of the plurality of pores of 32 μm.

### Example 2

A polishing pad was prepared in the same manner as in Example 1, except that a solid phase foaming agent, which had not been purified through the purification system for a solid phase foaming agent and had the characteristics of both the first pores and the second pores, was used and that the rotation speed of the mixing head was adjusted to 4,000 rpm. The polishing pad thus prepared had an average diameter (Dₐ) of the plurality of pores of 78 μm.

### Example 3

A polishing pad having an average diameter (Dₐ) of the plurality of pores of 15 μm was prepared in the same manner as in Example 1, except that a solid phase foaming agent, which had been purified through the purification system for a solid phase foaming agent and had the characteristics of the second pores, was used.

### Comparative Example 1

A polishing pad was prepared in the same manner as in Example 1, except that a solid phase foaming agent having the characteristics of the first pores was used. The polishing pad thus prepared had an average diameter (Dₐ) of the plurality of pores of 28 μm.

### TEST EXAMPLE

### Test Example 1: Measurement of the Number Average Diameter (Dₐ) of a Plurality of Pores

The polishing pads prepared in the Examples and the Comparative Examples were each cut into a square of 1 mm×1 mm (thickness: 2 mm), and the image area was observed with a scanning electron microscope (SEM) at a magnification of 200 times. The diameter of each pore was measured from an image obtained using an image analysis software, from which the average diameter (Dₐ) was calculated. The average diameter was defined as an average value obtained by dividing the sum of the diameters of the plurality of pores by the number of the pores in 1 mm² of the polishing surface.

### Test Example 2: Measurement of the Sphericity of a Plurality of Pores

The polishing pads prepared in the Examples and the Comparative Examples were each cut into a square of 1 mm×1 mm (thickness: 2 mm), and the pore diameters of the plurality of pores were measured using a 3D CT-scan (GE Corporation), from which it was calculated using the following Equation 1.

$$Sphericity = \frac{{{π}^{\frac{1}{3}} ( 6 {V}_{pore} )}^{\frac{2}{3}}}{{A}_{pore}} \qquad [ Equation 1 ]$$

In Equation 1, Aₚₒᵣₑ, is the cross-sectional area of pores, and Vₚₒᵣₑ is the volume of pores.

Specifically, when the pore diameter is r, Aₚₒᵣₑ was calculated as πr², Vₚₒᵣₑ=4/3πr³, and Da was the number average value of the pore diameters.

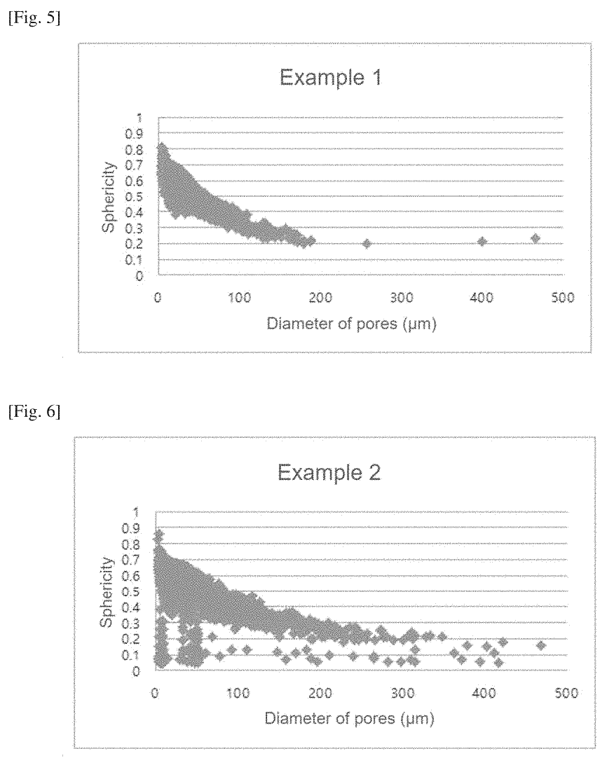

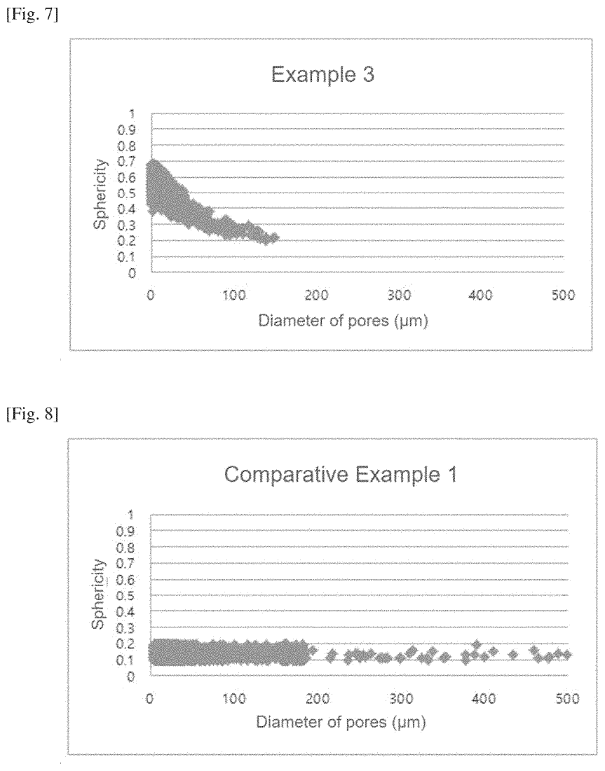

The average diameter and sphericity of a plurality of pores measured in Test Examples 1 and 2 are shown in Table 1 below, and the graphs of the sphericity with respect to the diameters of the plurality of pores are shown in FIGS. 5 to 8.

### Test Example 3: 3D CT-scan

The polishing pads of Comparative Example 1 and Example 1 were subjected to a 3D CT-scan (GE Corporation).

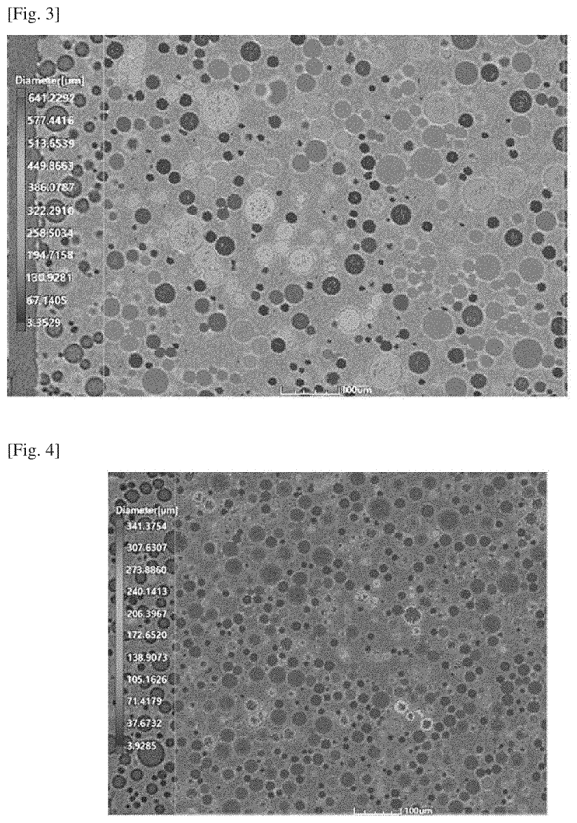

FIGS. 3 and 4 are each a cross-sectional image obtained by a 3D CT-scan of the polishing pads of Comparative Example 1 and Example 1.

FIG. 3 shows a 2D image of pores and their diameters for the measured cross-section. The pores are expressed in color according to the pore diameter. The pores are larger as the color changes from blue to red. It should be noted here that the pores marked in blue (diameter 200 μm or less) and pores marked in red (diameter 600 μm or more) are marked with different diameters even though they appear to have similar diameters on the 2D image. The reason is that for the red pores, the pores are aggregated, and the software recognizes them as a clustered pore. Thus, it can be seen that they are recognized as a large-sized pore (red) by the coalescence of pores rather than due to the difference in pore size.

On the other hand, in FIG. 4 measured according to Example 1 of the present invention, although a solid phase foaming agent having the same average particle diameter as that of FIG. 3 was used, there are no pores recognized as a large-sized pore due to the coalescence.

### Test Example 4: Polishing Rate (Removal Rate)

The initial polishing rate immediately after the polishing pads of the Examples and the Comparative Examples had been prepared was measured as follows.

A silicon semiconductor substrate (or wafer) having a diameter of 300 mm was deposited with silicon oxide by a CVD process. The polishing pad was mounted on a CMP machine, and the silicon semiconductor substrate was set with the silicon oxide layer thereof facing the polishing surface of the polishing pad. The silicon oxide layer was polished under a polishing load of 4.0 psi while it was rotated at a speed of 150 rpm for 60 seconds and a calcined ceria slurry was supplied onto the polishing pad at a rate of 250 ml/min. Upon completion of the polishing, the silicon semiconductor substrate was detached from the carrier, mounted in a spin dryer, washed with distilled water, and then dried with nitrogen for 15 seconds. The changes in the film thickness of the dried silicon semiconductor substrate before and after the polishing were measured using a spectral reflectometer type thickness measuring instrument (SI-F80R, Kyence). The polishing rate was calculated using the following Equation 2. The results are shown in Table 1 below.

Polishing rate(Å/min)=polished thickness of a silicon semiconductor substrate(Å)/polishing time (minute) [Equation 2]

### Test Example 5: Number of Scratches and Chatter Marks

After the polishing process was carried out using the polishing pads of the Examples and the Comparative Examples, the scratches and chatter marks appearing on the wafer surface upon the polishing was measured using wafer inspection equipment (AIT XP+, KLA Tencor) (threshold: 150, die filter threshold: 280).

The scratch means a substantially continuous linear scratch. For example, it means a defect of the shape as shown in FIG. 13.

Meanwhile, the chatter mark means a substantially discontinuous linear scratch. For example, it means a defect of the shape as shown in FIG. 14.

The results are shown in Table 1 below.

TABLE 1

| | Ex. 1 | Ex. 2 | Ex. 3 | C. Ex. 1 |
|---|---|---|---|---|
| Avg. particle | 25 | 25 | 10 | 25 |
| diameter of the | | | | |
| solid phase foaming | | | | |
| agent (μm) | | | | |
| Purification system | Used | Not used | Used | Used |
| for the solid phase | | | | |
| foaming agent | | | | |
| Avg. diameter (Dₐ) | 32 | 78 | 15 | 28 |
| of pores in the | | | | |
| polishing pad (μm) | | | | |
| Sphericity | 0.2 to 0.9 | 0.05 to 0.9 | 0.2 to 0.9 | 0.01 to less |
| | | | | than 0.2 |
| Volume % of pores | 100% | 63% | 100% | 0% |
| with a sphericity | | | | |
| of 0.2 to 0.9 | | | | |
| (based on the | | | | |
| total volume of a | | | | |
| plurality of pores) | | | | |
| Polishing rate | 2998 | 2919 | 2710 | 2805 |
| (Å/min) | | | | |
| No. of scratches | 195 | 391 | 201 | 775 |
| (count) | | | | |
| No. of chatter | 2.0 | 6.0 | 2.5 | 13.5 |
| marks (count) | | | | |

As can be seen from Table 1, the average diameter of the plurality of pores of the polishing pads of Examples 1 to 3 was 15 μm to 78 μm, and the volume of pores having a sphericity of 0.2 to 0.9 was adjusted to 63% by volume to 100% by volume based on the total volume of the plurality of pores. The coalescence phenomenon was controlled as compared with the polishing pad of Comparative Example 1.

Specifically, in the polishing pads of Examples 1 and 3 prepared by using the purification system for a solid phase foaming agent and adopting the rotation speed of the mixing head at 3,000 rpm, the volume of pores having a sphericity of 0.2 to 0.9 was 100/by volume. This indicates that the shape of the pores was uniform and there was almost no coalescence phenomenon. It can be seen that the number of scratches and the number of chatter marks were significantly reduced as compared with Comparative Example 1.

In addition, in the polishing pad of Example 2 prepared by not using the purification system for a solid phase foaming agent and adopting the rotation speed of the mixing head at 4,000 rpm, the sphericity was 0.05 to 0.9 since it contained pores of a low sphericity, whereas the volume of pores having a sphericity of 0.2 to 0.9 was still as high as 63% by volume. In this case, the number of scratches was increased as compared with that of the polishing pad of Example 1 since it contained pores having a sphericity of less than 0.2, whereas the number of chatter marks was significantly reduced to 6 or less as compared with Comparative Example 1.

Meanwhile, in Example 3 in which the average diameter of pores in the polishing pad was decreased to 15 μm as compared with the average diameter of pores in Examples 1 and 2, the volume of pores having a sphericity of 0.2 to 0.9 was 100% by volume, and the number of scratches and the number of chatter marks were still remarkably superior to those of Comparative Example 1.

In contrast, in Comparative Example 1 in which the volume of pores having a sphericity of 0.2 to 0.9 was 0% by volume although a solid phase foaming agent purified by the purification system for a solid phase foaming agent was used, the number of scratches and the number of chatter marks were remarkably increased. A polishing pad in which the volume of pores with a sphericity of 0.2 to 0.9 is 0% means that the pores were aggregated and contained a lot of pores with a low sphericity. As a result, the number of scratches was increased by 4.5 times or more and the number of chatter marks was increased by times or more as compared with the polishing pad of Example 1.

Furthermore, as can be seen from FIGS. 5 to 8, in the polishing pads of Examples 1 to 3, the pores with a sphericity of 0.2 to 0.9 were almost distributed within the range of 5 μm to 200 μm of the average diameter of the plurality of pores. In contrast, in Comparative Example 1, the pores having a low sphericity of less than 0.2 were distributed mostly according to the pore diameter.

[Reference Numeral of the Drawings]

| | |
|---|---|
| 110: polishing pad | 120: platen |
| 130: semiconductor substrate | 140: nozzle |
| 150: polishing slurry | 160: polishing head |
| 170: conditioner | |
| 10a, 10c: pipe | 30a, 30b: filter unit |
| 31: filter housing | 32: filter cover |
| 33: filter member | 311: filter space |
| 312: filter inlet | 321: filter outlet |
| 331: mounting member | 332: magnet |
| 50: classification unit | 51: classification housing |
| 53: vortex generating member | 54: discharge filter |
| 56: vibration generating member | |
| 511: classification space | 511a: central axis |
| 512: classification inlet hole | 513: first microsphere |
| | discharge hole |
| 514: second microsphere | |
| discharge hole | |
| 515: gas supply hole | 516: gas discharge hole |
| A: flow of the fluidizing gas | B: flow of the solid phase |
| | foaming agent |
| C: vibration arrow | S1, S2: sphericity |

1. A polishing pad, which comprises a plurality of pores, wherein the average diameter (Dₐ) of the plurality of pores is 5 μm to 200 μm, and the volume of pores having a sphericity of 0.2 to 0.9 according to the following Equation 1 is 50% by volume to 100% by volume based on the total volume of the plurality of pores:
$$Sphericity = \frac{{{π}^{\frac{1}{3}} ( 6 {V}_{pore} )}^{\frac{2}{3}}}{{A}_{pore}} \qquad [ Equation 1 ]$$
in Equation 1, Aₚₒᵣₑ is the cross-sectional area of pores, and Vₚₒᵣₑ is the volume of pores.

2. The polishing pad of claim 1, wherein the plurality of pores have a sphericity of 0.001 to less than 1.0, and the polishing pad comprises one or more pores selected from first pores having a sphericity of 0.001 to less than 0.2 and second pores having a sphericity of 0.2 to less than 1.0.

3. The polishing pad of claim 2, wherein the total volume of the second pores is greater than the total volume of the first pores.

4. The polishing pad of claim 2, which does not comprise the first pores.

5. The polishing pad of claim 1, wherein the Dₐ is 7 μm to 100 μm, and the volume of pores having a sphericity of 0.2 to 0.9 is 60% by volume to 100% by volume based on the total volume of the plurality of pores.

6. The polishing pad of claim 1, wherein the plurality of pores are derived from a solid phase foaming agent.

7. The polishing pad of claim 6, wherein the solid phase foaming agent is purified by a purification system.

8. A process for preparing a polishing pad, which comprises:
mixing a urethane-based prepolymer, a solid phase foaming agent, and a curing agent to prepare a raw material mixture; and
injecting the raw material mixture into a mold and molding the raw material mixture,
wherein the polishing pad comprises a plurality of pores,
the average diameter (Dₐ) of the plurality of pores is 5 μm to 200 μm, and
the volume of pores having a sphericity of 0.2 to 0.9 according to the following Equation 1 is 50% by volume to 100% by volume based on the total volume of the plurality of pores:
$$Sphericity = \frac{{{π}^{\frac{1}{3}} ( 6 {V}_{pore} )}^{\frac{2}{3}}}{{A}_{pore}} \qquad [ Equation 1 ]$$
in Equation 1, Aₚₒᵣₑ is the cross-sectional area of pores, and Vₚₒᵣₑ is the volume of pores.

9. The process for preparing a polishing pad of claim 8, wherein the solid phase foaming agent is purified by a purification system.

10. The process for preparing a polishing pad of claim 9, wherein the average particle diameter (D50) of the purified solid phase foaming agent is 5 μm to 200 μm.

11. The process for preparing a polishing pad of claim 8, wherein the mixing is carried out by a mixing system at a rotational speed of 500 rpm to 10,000 rpm.

12. A process for preparing a semiconductor device, which comprises:
mounting a polishing pad comprising a polishing layer comprising a plurality of pores on a platen; and
relatively rotating the polishing pad and a semiconductor substrate while a polishing surface of the polishing layer and a surface of the semiconductor substrate are in contact with each other to polish the surface of the semiconductor substrate,
wherein the polishing pad comprises a plurality of pores,
the average diameter (Dₐ) of the plurality of pores is 5 μm to 200 μm, and
the volume of pores having a sphericity of 0.2 to 0.9 according to the following Equation 1 is 50% by volume to 100% by volume based on the total volume of the plurality of pores:
$$Sphericity = \frac{{{π}^{\frac{1}{3}} ( 6 {V}_{pore} )}^{\frac{2}{3}}}{{A}_{pore}} \qquad [ Equation 1 ]$$
in Equation 1, Aₚₒᵣₑ is the cross-sectional area of pores, and Vₚₒᵣₑ, is the volume of pores.
